(19) United States
(12) Patent Application Publication
(10) Pub. No.: US 2025/0271757 A1
(43) Pub. Date: Aug. 28, 2025

(54) PHOTOSENSITIVE RESIN COMPOSITION, CURED PRODUCT, AND SEMICONDUCTOR ELEMENT

(71) Applicant: Resonac Corporation, Tokyo (JP)

(72) Inventors: Fumihiko KAWAUCHI, Tokyo (JP); Tatsuya MAKINO, Tokyo (JP); Guillermo FERNANDEZ ZAPICO, Tokyo (JP)

(21) Appl. No.: 18/859,427

(22) PCT Filed: Nov. 7, 2023
(86) PCT No.: PCT/JP2023/040068

§ 371 Date: Oct. 23, 2024

(30) Foreign Application Priority Data
Nov. 8, 2022 (WO) PCT/JP2022/041551

(51) Int. Cl. G03F 7/028; C08G 73/14; H01L 23/532

(52) U.S. Cl. CPC G03F 7/028; C08G 73/14; H01L 23/5329

(57) ABSTRACT

The present disclosure relates to a photosensitive resin composition containing a base resin containing a maleimide compound; a crosslinking agent; and a photopolymerization initiator, in which the maleimide compound is a reaction product of a tetracarboxylic dianhydride, a diamine, and maleic anhydride, and the diamine includes a dimer diamine and a second diamine other than the dimer diamine.

### TECHNICAL FIELD

The present disclosure relates to a photosensitive resin composition, a cured product, and a semiconductor element.

### BACKGROUND ART

In accordance with high integration, miniaturization, and micronization of semiconductor elements, insulating films used for surface protective layers, interlayer insulating layers, and redistribution layers of the semiconductor elements are required to have more excellent electrical characteristics, heat resistance, mechanical characteristics, and the like. As a material for forming an insulating film having such characteristics, a photosensitive resin composition containing an alkali-soluble resin has been developed (see, for example, Patent Literatures 1, 2, and 3). These photosensitive resin compositions are applied onto a substrate and dried to form a resin film, and the resin film is exposed and developed to obtain a patterned resin film (a film on which a pattern is formed). Then, a patterned cured film (cured film on which a pattern is formed) can be formed by thermally curing the patterned resin film, and the patterned cured film can be used as an insulating film.

### CITATION LIST

### Patent Literature

Patent Literature 1: JP 2008-309885 A
Patent Literature 2: JP 2007-057595 A
Patent Literature 3: WO 2010/073948 A1

### SUMMARY OF INVENTION

### Technical Problem

A photosensitive resin composition for forming an insulating film of a redistribution layer is required to form an insulating film having excellent photosensitive characteristics and low dielectric characteristics. Therefore, an object of the present disclosure is to provide a photosensitive resin composition capable of forming an insulating film having excellent photosensitive characteristics and low dielectric characteristics.

### Solution to Problem

An aspect of the present disclosure relates to a photosensitive resin composition, a cured product, and a semiconductor element described below.

[1] A photosensitive resin composition containing: a base resin containing a maleimide compound; a crosslinking agent; and a photopolymerization initiator, in which the maleimide compound is a reaction product of a tetracarboxylic dianhydride, a diamine, and maleic anhydride, and the diamine includes a dimer diamine and a second diamine other than the dimer diamine.

[2] The photosensitive resin composition according to [1], in which the tetracarboxylic dianhydride is at least one selected from the group consisting of 4,4′-(4,4′-isopropylidenediphenoxy)diphthalic anhydride, 4,4′-oxydiphthalic anhydride, and 1,2,3,4-butanetetracarboxylic dianhydride.

[3] The photosensitive resin composition according to [1], in which the tetracarboxylic dianhydride includes 1,3,3a,4,5,9b-hexahydro-5(tetrahydro-2,5-dioxo-3-furanyl)naphtho[1,2-C]furan-1,3-dione.

[4] The photosensitive resin composition according to any one of [1] to [3], in which the second diamine includes at least one selected from the group consisting of meta-xylylenediamine, 4,4′-diaminodiphenylmethane, 1,3-diaminopropane, and 2,2-bis[4-(4-aminophenoxy)phenyl]propane.

[5] The photosensitive resin composition according to any one of [1] to [3], in which the second diamine includes norbornanediamine.

[6] The photosensitive resin composition according to any one of [1] to [5], in which the crosslinking agent includes a polymerizable crosslinking agent having a (meth)acryloyl group.

[7] The photosensitive resin composition according to [6], in which the polymerizable crosslinking agent having a (meth)acryloyl group includes at least one selected from the group consisting of tricyclodecanedimethanol di(meth)acrylate, tris(2-(meth)acryloyloxyethyl)isocyanurate, and dioxane glycol di(meth)acrylate.

[8] The photosensitive resin composition according to any one of [1] to [6], in which the crosslinking agent includes a polymerizable crosslinking agent having an allyl group or a vinyl group.

[9] The photosensitive resin composition according to [8], in which the polymerizable crosslinking agent having an allyl group or a vinyl group includes at least one selected from the group consisting of 1,3,4,6-tetraallyl glycoluril, triallyl isocyanurate, diallyl isocyanurate, and a polyvinyl benzyl ether compound.

[10] The photosensitive resin composition according to any one of [1] to [9], further containing a thermal polymerization initiator.

[11] A cured product of the photosensitive resin composition according to any one of [1] to [10].

[12] A semiconductor element including a redistribution layer containing a cured product of the photosensitive resin composition according to any one of [1] to [10].

### Advantageous Effects of Invention

According to the present disclosure, it is possible to provide a photosensitive resin composition capable of forming an insulating film having excellent photosensitive characteristics and low dielectric characteristics, a cured product of a photosensitive resin composition having low dielectric characteristics, and a semiconductor element including a redistribution layer containing the cured product.

### DESCRIPTION OF EMBODIMENTS

Hereinafter, preferred embodiments of the present disclosure will be described in detail. However, the present invention is not limited to the following embodiments, and various modifications can be made within the scope of the gist of the present invention.

In the present specification, a numerical range indicated using “to” indicates a range including numerical values described before and after “to” as a minimum value and a maximum value, respectively. In the numerical range described in stages in the present specification, an upper limit value or a lower limit value of a numerical range of a certain stage can be arbitrarily combined with an upper limit value or a lower limit value of a numerical range of another stage. In the numerical range described in the present specification, the upper limit value or the lower limit value of the numerical range may be replaced with a value shown in Examples. “A or B” may include either A or B, or may include both A and B. The materials exemplified in the present specification can be used alone or in combination of two or more kinds thereof unless otherwise specified. When a plurality of materials corresponding to the respective components are present in the composition, a content of each component in the composition means the total amount of the plurality of materials present in the composition unless otherwise specified.

In the present specification, the “layer” and the “film” include not only a structure having a shape formed on the entire surface but also a structure having a shape formed on a part thereof when observed as a plan view. The term “step” includes not only an independent step but also a step that cannot be clearly distinguished from other steps as long as the intended purpose of the step is achieved.

In the present specification, “(meth)acrylate” means at least one of “acrylate” and “methacrylate” corresponding thereto, and the same applies to other similar expressions such as (meth)acrylic acid and (meth)acryloyl. In the present specification, the “solid content” refers to a non-volatile content excluding a volatile substance (water, a solvent, or the like) contained in a photosensitive resin composition, and also includes a component in a liquid, syrupy, or waxy state at room temperature (around 25° C.).

### [Photosensitive Resin Composition]

A photosensitive resin composition according to the present embodiment contains a base resin containing a maleimide compound, a crosslinking agent, and a photopolymerization initiator as essential components. The photosensitive resin composition according to the present embodiment may further contain a thermal polymerization initiator, a coupling agent, a rust inhibitor, a polymerization inhibitor, and the like, as necessary. The photosensitive resin composition according to the present embodiment is a negative photosensitive resin composition, and a cured product of the photosensitive resin composition can be suitably used as an insulating film for a redistribution layer. Hereinafter, each component used in the photosensitive resin composition of the present embodiment will be described in more detail.

### (Base Resin)

The base resin contains a maleimide compound (hereinafter, also referred to as “component (A)”). The maleimide compound according to the present embodiment is a reaction product of a tetracarboxylic dianhydride, a diamine, and maleic anhydride. The component (A) is a compound obtained by reacting a tetracarboxylic dianhydride (a1) (hereinafter, also referred to as “component (a1)”), a diamine (a2) (hereinafter, also referred to as “component (a2)”), and maleic anhydride (a3) (hereinafter, also referred to as “component (a3)”).

Examples of the component (a1) include pyromellitic anhydride, 4,4′-oxydiphthalic dianhydride, 4,4′-(hexafluoroisopropylidene)diphthalic anhydride, 1,2,3,4-butanetetracarboxylic dianhydride, 3,3′,4,4′-diphenylsulfonetetracarboxylic dianhydride, 3,3′,4,4′-biphenyltetracarboxylic dianhydride, 3,3′,4,4′-benzophenonetetracarboxylic dianhydride, 4,4′-(4,4′-isopropylidenediphenoxy)diphthalic anhydride, 1,3,3a,4,5,9b-hexahydro-5(tetrahydro-2,5-dioxo-3-furanyl)naphtho[1,2-C]furan-1,3-dione, bis(1,3-dioxo-1,3-dihydroisobenzofuran-5-carboxylic acid) 1,4-phenylene, 1,2,3,4-cyclobutane tetracarboxylic dianhydride, 1,2,3,4-cyclopentane tetracarboxylic dianhydride, 1,2,3,4-tetramethyl-1,2,3,4-cyclobutane tetracarboxylic dianhydride, bicyclo[2.2.2]oct-7-ene-2,3,5,6-tetracarboxylic dianhydride, 4,4′-(ethyne-1,2-diyl)diphthalic anhydride, 5-(2,5-dioxotetrahydrofuryl)-3-methyl-3-cyclohexene-1,2-dicarboxylic anhydride, dicyclohexyl-3,4,3′,4′-tetracarboxylic dianhydride, 3,4′-oxydiphthalic anhydride, 3,4′-biphthalic anhydride, 9,9-bis(3,4-dicarboxyphenyl)fluorene dianhydride, norbornane-2-spiro-α-cyclopentanone-α′-spiro-2”-norbornane-5,5”,6,6”-tetracarboxylic dianhydride, 5,5′-bis-2-norbornene-5,5′,6,6′-tetracarboxylic acid-5,5′,6,6′-dianhydride, and 9,9-bis[4-(3,4-dicarboxyphenoxy)phenyl]fluorene dianhydride. The components (a1) may be used alone or in combination of two or more kinds thereof.

The component (a1) may include at least one selected from the group consisting of 4,4′-(4,4′-isopropylidenediphenoxy)diphthalic anhydride (BPADA), 4,4′-oxydiphthalic anhydride (ODPA), and 1,3,3a,4,5,9b-hexahydro-5(tetrahydro-2,5-dioxo-3-furanyl)naphtho[1,2-C]furan-1,3-dione (TDA) from the viewpoint of low dielectric characteristics, and preferably includes TDA from the viewpoint of dielectric characteristics, photosensitive characteristics, and heat resistance.

The component (a2) includes a dimer diamine (first diamine) and a second diamine other than the dimer diamine. By using a dimer diamine as the diamine, a cured product excellent in dielectric characteristics can be obtained. On the other hand, when only a dimer diamine is used as the diamine, an elastic modulus and a Tg of the cured product decrease. In contrast, when the second diamine is used in combination with a dimer diamine, the elastic modulus and the Tg of the cured product can be improved.

The dimer diamine is, for example, a compound derived from a dimer acid which is a dimer of an unsaturated fatty acid such as oleic acid as described in Japanese Unexamined Patent Publication No. 119-12712. In the present embodiment, a known dimer diamine can be used without particular limitation. The dimer diamine may be a branched aliphatic diamine.

As the dimer diamine, a diamine represented by the following Formula (1) may be used.

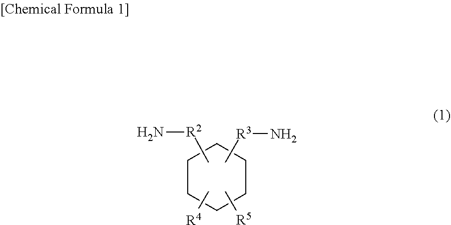

In Formula (1), R² and R³ each independently represent an alkylene group having 4 to 50 carbon atoms, R⁴ represents an alkyl group having 4 to 50 carbon atoms, and R⁵ represents an alkyl group having 2 to 50 carbon atoms.

From the viewpoint of further improvement of flexibility and ease of synthesis, R² and R³ are each independently preferably an alkylene group having 5 to 25 carbon atoms, more preferably an alkylene group having 6 to 10 carbon atoms, and still more preferably an alkylene group having 7 to 10 carbon atoms. From the same viewpoint, R⁴ is preferably an alkyl group having 5 to 25 carbon atoms, more preferably an alkyl group having 6 to 10 carbon atoms, and still more preferably an alkyl group having 7 to 10 carbon atoms. From the same viewpoint, R⁵ is preferably an alkyl group having 3 to 25 carbon atoms, more preferably an alkyl group having 4 to 10 carbon atoms, and still more preferably an alkyl group having 5 to 8 carbon atoms.

Examples of a commercially available product of the dimer diamine include PRIAINE 1075 and PRIAVINE 1074 (both manufactured by Croda Japan K. K.).

The second diamine is a diamine that does not correspond to the dimer diamine described above. The second diamine may be a linear diamine. The second diamines may be used alone or in combination of two or more kinds thereof.

Examples of the second diamine include 1,3-diaminopropane, norbornanediamine, 1,3-bis(aminomethyl)cyclohexane, 1,4-bis(aminomethyl)cyclohexane, bis(aminomethyl)norbornane, meta-xylylenediamine, 4,4′-diaminodiphenylmethane, 2,2-bis[4-(4-aminophenoxy)phenyl]propane, 1,3-bis[2-(4-aminophenyl)-2-propyl]benzene, 4,4′-diamino-2,2′-bis(trifluoromethyl)biphenyl, 2,2-bis[4-(4-aminophenoxy)phenyl]hexafluoropropane, 4,4′-(hexafluoroisopropylidene)dianiline, 3(4),8(9)-bis(aminomethyl)tricyclo[5.2.1.0(2,6)]decane, 1,3-cyclohexanediamine, 1,4-cyclohexanediamine, isophoronediamine, 4,4′-methylenebis(cyclohexylamine), 4,4′-methylenebis(2-methylcyclohexylamine), 1,1-bis(4-aminophenyl)cyclohexane, 4,4′-methylenedianiline, 4,4′-ethylenedianiline, 4,4′-methylenebis(2,6-diethylaniline), 4,4′-methylenebis(2-ethyl-6-methylaniline), 4,4′-diaminodiphenyl ether, 3,3′-diaminodiphenyl ether, 1,3-bis(4-aminophenoxy)benzene, 1,3′-bis(3-aminophenoxy)benzene, 1,4′-bis(4-aminophenoxy)benzene, bis[4-(4-aminophenoxy)phenyl]methane, bis[4-(4-aminophenoxy)phenyl]ether, bis[4-(4-aminophenoxy)phenyl]ketone, para-phenylenediamine, ortho-phenylenediamine, meta-phenylenediamine, bis[4-(3-aminophenoxy)phenyl]sulfone, bis[4-(4-aminophenoxy)phenyl]sulfone, 9,9-bis(4-aminophenyl)fluorene, 9,9-bis[4-(4-aminophenoxy)phenyl]fluorene, 2,7-diaminofluorene, 2,2′-dimethylbenzidine (4,4′-diamino-2,2′-dimethylbiphenyl), 4,4′-diamino-2,2′-diethylbiphenyl, 4,4′-bis(4-aminophenoxy)biphenyl, 4,4′-diamino-3,3′-dimethylbiphenyl, 4,4′-diamino-3,3′-diethylbiphenyl, 4,4′-diamino-3,3′,5,5′-tetramethylbiphenyl, 4,4′-diamino-3,3′,5,5′-tetraethylbiphenyl, 4,4′-diamino-2,2′-dimethoxybiphenyl, and 4,4′-diamino-3,3′-dimethoxybiphenyl.

The second diamine may include at least one selected from the group consisting of norbornanediamine, meta-xylylenediamine, 4,4′-diaminodiphenylmethane, and 2,2-bis[4-(4-aminophenoxy)phenyl]propane from the viewpoint of improving the glass transition temperature (Tg) of the cured product, and the second diamine preferably includes norbornanediamine from the viewpoint of dielectric characteristics, photosensitive characteristics, and heat resistance.

In the component (a2), a molar ratio of the second diamine (the number of moles of the second diamine/(the number of moles of the dimer diamine+the number of moles of the second diamine)) may be 5 to 90 mol %, 10 to 85 mol %, 20 to 80 mol %, 25 to 75 mol %, 30 to 70 mol %, or 30 to 50 mol %. When the ratio is 5 mol % or more, the elastic modulus and the Tg of the cured product can be easily increased, and when the ratio is 90 mol % or less, a cured product having lower dielectric characteristics can be formed.

A method for preparing the component (A) is not limited. The component (A) may be prepared, for example, by reacting the component (a1) with the component (a2) to synthesize an amine-terminated compound, and then reacting the amine-terminated compound with an excessive component (a3).

The component (A) can be prepared by various known methods. For example, first, the component (a1) and the component (a2) are subjected to a polyaddition reaction at a temperature of about 60 to 120° C. and preferably 70 to 90° C., for usually about 0.1 to 2 hours and preferably 0.1 to 1.0 hour. Next, the obtained polyaddition product is further subjected to an imidization reaction, that is, a dehydration ring-closing reaction, at a temperature of about 80 to 250° C. and preferably 100 to 200° C. for about 0.5 to 30 hours and preferably 0.5 to 10 hours. Subsequently, the product obtained by the dehydration ring-closing reaction and the component (a3) are subjected to a maleimidation reaction, that is, a dehydration ring-closing reaction, at a temperature of about 60 to 250° C. and preferably 80 to 200° C. for about 0.5 to 30 hours and preferably 0.5 to 10 hours, thereby obtaining a target component (A).

The component (A) may be a compound obtained by reacting the component (a1), the component (a2), a triamine, and the component (a3). Examples of the triamine include tris(2-aminomethyl)amine, tris(2-aminoethyl)amine, tris(2-aminopropyl)amine, 2-(aminomethyl)-2-methyl-1,3-propanediamine, a trimer triamine, 3,4,4′-triaminodiphenyl ether, 1,2,4-triaminobenzene, 1,3,5-triaminobenzene, 1,2,3-triaminobenzene, 1,3,5-triazine-2,4,6-triamine, 2,4,6-triaminopyrimidine, 1,3,5-tris(4-aminophenyl)benzene, and 1,3,5-tris(4-aminophenoxy)benzene.

In the imidization reaction or the maleimidization reaction, various known reaction catalysts, dehydrating agents, and organic solvents can be used.

Examples of the reaction catalyst include aliphatic tertiary amines such as triethylamine, aromatic tertiary amines such as dimethylaniline, heterocyclic tertiary amines such as pyridine, picoline, and isoquinoline, and organic acids such as methanesulfonic acid and p-toluenesulfonic acid monohydrate. The reaction catalysts can be used alone or in combination of two or more kinds thereof. Examples of the dehydrating agent include aliphatic acid anhydrides such as acetic anhydride and aromatic acid anhydrides such as benzoic anhydride.

Examples of the organic solvent include aromatic hydrocarbons such as benzene, toluene, xylene, and mesitylene; alcoholic solvents such as methanol, ethanol, isopropyl alcohol, butanol, pentanol, hexanol, propanediol, and phenol; ketone solvents such as acetone, methyl isobutyl ketone, methyl ethyl ketone, pentanone, hexanone, cyclopentanone, cyclohexanone, isophorone, and acetophenone; cellosolves such as methyl cellosolve and ethyl cellosolve; ester-based solvents such as methyl acetate, ethyl acetate, butyl acetate, methyl propionate, butyl formate, and γ-butyrolactone; glycol ether-based solvents such as ethylene glycol mono-n-butyl ether, ethylene glycol mono-iso-butyl ether, ethylene glycol mono-tert-butyl ether, diethylene glycol mono-n-butyl ether, diethylene glycol mono-iso-butyl ether, triethylene glycol mono-n-butyl ether, and tetraethylene glycol mono-n-butyl ether; and nitrogen-containing compounds such as N,N-dimethylformamide, N,N-dimethylacetamide, N-methyl-2-pyrrolidone, N-ethyl-2-pyrrolidone, 3-methoxy-N,N-dimethylpropanamide, and 3-butoxy-N,N-dimethylpropanamide. The organic solvents can be used alone or in combination of two or more kinds thereof.

The component (A) can be purified by various known methods, and the purity can be increased. For example, first, the component (A) dissolved in an organic solvent and pure water are placed in a separatory funnel. Next, the separatory funnel is shaken and allowed to stand. Subsequently, after an aqueous layer and an organic layer are separated, only the organic layer is recovered, such that the component (A) can be purified.

A molecular weight of the component (A) can be controlled by the numbers of moles of the component (a1) and the component (a2), and the molecular weight can be made smaller as the number of moles of the component (a1) is smaller than the number of moles of the component (a2). For the purpose of easily achieving the effects of the present disclosure, [the number of moles of the component (a1)]/[the number of moles of the component (a2)] is usually in a range of about 0.30 to 0.85 and preferably 0.50 to 0.80.

The molecular weight of the component (A) may be 3000 to 100000, 4000 to 80000, 5000 to 60000, 6000 to 40000, or 7000 to 20000, in terms of weight average molecular weight (Mw) from the viewpoint of solubility in a solvent and heat resistance. The Mw can be measured by gel permeation chromatography (GPC), and can be converted using a calibration curve of standard polystyrene.

### (Crosslinking Agent)

As the crosslinking agent (hereinafter, also referred to as “component (B)”), a polyfunctional compound having two or more polymerizable groups can be used. The crosslinking agent can crosslink the crosslinking agents and can be crosslinked with the component (A) at the time of exposure of a photosensitive layer, for example. In addition, the crosslinking agent can crosslink the polymerizable crosslinking agents at the time of heating the resin film after pattern formation, for example. The component (B) may be a polymerizable crosslinking agent. The polymerizable group may be a photopolymerizable group or a thermopolymerizable group. Examples of the polymerizable group include a (meth)acryloyl group, an allyl group, and a vinyl group. The crosslinking agents can be used alone or in combination of two or more kinds thereof.

The resin composition according to the present embodiment may contain a polymerizable crosslinking agent having a (meth)acryloyl group as a crosslinking agent from the viewpoint of excellent dielectric characteristics. The polymerizable crosslinking agent having a (meth)acryloyl group can crosslink the crosslinking agents and can be crosslinked with the component (A) at the time of exposure of the photosensitive layer. The polymerizable crosslinking agent having a (meth)acryloyl group may be an acrylate compound or a methacrylate compound. The component (B) may include a methacrylate compound from the viewpoint of excellent dielectric characteristics.

Examples of the polymerizable crosslinking agent having a (meth)acryloyl group include tricyclodecanedimethanol di(meth)acrylate, tris(2-(meth)acryloyloxyethyl)isocyanurate, dioxane glycol di(meth)acrylate, alkoxylated glycerin tri(meth)acrylate, trimethylolpropane tri(meth)acrylate, alkoxylated trimethylolpropane tri(meth)acrylate, pentaerythritol tri(meth)acrylate, pentaerythritol tetra(meth)acrylate, alkoxylated pentaerythritol tetra(meth)acrylate, 1,6-hexanediol di(meth)acrylate, 1,9-nonanediol di(meth)acrylate, 1,10-decanediol di(meth)acrylate, neopentyl glycol di(meth)acrylate, ethoxylated bisphenol A di(meth)acrylate, propoxylated ethoxylated bisphenol A (meth)acrylate, dipentaerythritol poly(meth)acrylate, alkoxylated dipentaerythritol poly(meth)acrylate, ethoxylated isocyanuric acid tri(meth)acrylate, polyethylene glycol di(meth)acrylate, and polypropylene glycol di(meth)acrylate.

The polymerizable crosslinking agent having a (meth)acryloyl group may include at least one selected from the group consisting of tricyclodecanedimethanol di(meth)acrylate, tris(2-(meth)acryloyloxyethyl)isocyanurate, and dioxane glycol di(meth)acrylate from the viewpoint of excellent heat resistance, dielectric characteristics, and photosensitive characteristics, and may include tricyclodecanedimethanol di(meth)acrylate from the viewpoint of excellent compatibility with the component (A).

The resin composition according to the present embodiment may contain, as the crosslinking agent, a polymerizable crosslinking agent having an allyl group or a vinyl group from the viewpoint of dielectric characteristics and heat resistance. The polymerizable crosslinking agent having an allyl group or a vinyl group can crosslink the polymerizable crosslinking agents at the time of heating the resin film after pattern formation.

Examples of the polymerizable crosslinking agent having an allyl group include 1,3,4,6-tetraallyl glycoluril, triallyl isocyanurate, diallyl monoglycidyl isocyanurate, diallyl monomethyl isocyanurate, diallyl isocyanurate, triallyl trimellitate, and triallyl ortho-formate.

Examples of the polymerizable crosslinking agent having a vinyl group include a polyvinyl benzyl compound and a polyvinyl benzyl ether compound.

The polymerizable crosslinking agent having an allyl group or a vinyl group may include at least one selected from the group consisting of 1,3,4,6-tetraallyl glycoluril, triallyl isocyanurate, diallyl isocyanurate, and a polyvinyl benzyl ether compound from the viewpoint of dielectric characteristics and photosensitive characteristics.

From the viewpoint of further improving a balance between the low dielectric characteristics and the photosensitive characteristics, a content of the component (B) is preferably less than 50 parts by mass, and may be 1 to 45 parts by mass, 5 to 40 parts by mass, 8 to 30 parts by mass, or 10 to 20 parts by mass, when the total amount of the component (A) and the component (B) is 100 parts by mass.

### (Photopolymerization Initiator)

The photopolymerization initiator (hereinafter, also referred to as “component (C)”) is not particularly limited as long as it is a compound that initiates polymerization by radiation with an active ray (ultraviolet ray or the like), and examples thereof include an alkylphenone-based photopolymerization initiator, an acylphosphine oxide-based photopolymerization initiator, an intramolecular hydrogen abstraction type photopolymerization initiator, and an oxime ester-based photopolymerization initiator.

The alkylphenone-based photopolymerization initiator can be purchased as, for example, Omnirad 651, Omnirad 184, Omnirad 1173, Omnirad 2959, Omnirad 127, Omnirad 907, Omnirad 369, or Omnirad 379EG manufactured by IGM Resins B. V., or the like. The acylphosphine oxide-based photopolymerization initiator can be purchased as, for example, Omnirad 819 or Omnirad TPO H manufactured by IGM Resins B. V., or the like. The intramolecular hydrogen abstraction type photopolymerization initiator can be purchased as, for example, Omnirad MBF or Omnirad 754 manufactured by IGM Resins B. V., or the like. The oxime ester-based photopolymerization initiator can be purchased as, for example, Irgacure OXE01 or Irgacure OXE02 manufactured by BASF Japan Ltd., or the like. In order to promote the photoreaction, a titanocene-based photopolymerization initiator (for example, Irgacure 784, manufactured by BASF Japan Ltd.) may be used in combination.

A content of the component (C) may be 0.1 to 10 parts by mass, 0.5 to 8 parts by mass, or 1 to 5 parts by mass, with respect to 100 parts by mass of the total amount of the component (A) and the component (B) in terms of easily obtaining excellent resolution.

### (Thermal Polymerization Initiator)

The photosensitive resin composition according to the present embodiment may further contain a thermal polymerization initiator as the component (D) from the viewpoint of promoting a polymerization reaction of a thermally polymerizable crosslinking agent. As the component (D), a compound that is decomposed by heating during curing to generate radicals and promotes the polymerization reaction of the component (A) and the component (B) is preferable. Examples of the component (D) include an organic peroxide.

Examples of the organic peroxide include methyl ethyl ketone peroxide, methylcyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl 4,4-bis(t-butylperoxy)valerate, 2,2-bis(t-butylperoxy)butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy)hexane, α,α′-bis(t-butylperoxy)diisopropylbenzene, t-butylcumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl)peroxydicarbonate, α,α′-bis(neodecanoylperoxy)diisopropylbenzene, cumylperoxyneodecanoate, 1,1,3,3,-tetramethylbutylperoxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy)hexane, 1,1,3,3-tetramethylbutylperoxy-2-ethylhexanoate, 1-cyclohexyl-1-methylethylperoxy-2-ethylhexanoate, t-hexylperoxy-2-ethylhexanoate, t-butylperoxy-2-ethylhexanoate, t-butylperoxyisobutyrate, t-butylperoxymaleic acid, t-butylperoxylaurate, t-butylperoxy-3,5,5-trimethylhexanoate, t-butylperoxyisopropyl monocarbonate, t-butylperoxy-2-ethylhexyl monocarbonate, 2,5-dimethyl-2,5-bis(benzoylperoxy)hexane, t-butyl peroxyacetate, t-hexyl peroxybenzoate, t-butyl peroxy-m-toluoyl benzoate, t-butyl peroxybenzoate, bis(t-butylperoxy)isophthalate, t-butylperoxyallyl monocarbonate, and 3,3′,4,4′-tetra(t-butylperoxycarbonyl)benzophenone. The organic peroxides can be used alone or in combination of two or more kinds thereof.

A content of the component (D) is not particularly limited, and may be 0.1 to 10.0 parts by mass, 0.5 to 5.0 parts by mass, or 0.7 to 3.0 parts by mass, with respect to 100 parts by mass of the total amount of the component (A) and the component (B).

### (Coupling Agent)

The photosensitive resin composition according to the present embodiment may further contain a coupling agent from the viewpoint of improving the adhesion of the cured product of the photosensitive resin composition. The coupling agent may be a silane coupling agent. The silane coupling agent may have, for example, a group such as a vinyl group, an epoxy group, a styryl group, an acryloyl group, a methacryloyl group, an amino group, a ureido group, an isocyanate group, an isocyanurate group, or a mercapto group.

Examples of the silane coupling agent having a vinyl group include KBM-1003 and KBE-1003 (trade name, manufactured by Shin-Etsu Chemical Co., Ltd., the same applies hereinafter). Examples of the silane coupling agent having an epoxy group include KBM-303, 402, and 403, KBE-402 and 403, X-12-981S, and X-12-984S. Examples of the silane coupling agent having a styryl group include KBM-1403. Examples of the silane coupling agent having a methacryloyl group include KBM-502 and 503 and KBE-502 and 503. Examples of the silane coupling agent having an acryloyl group include KBM-5103, X-12-1048, and X-12-1050. Examples of the silane coupling agent having an amino group include KBM-602, 603, 903, 573, and 575, KBE-903 and 9103P, and X-12-972F. Examples of the silane coupling agent having a ureido group include KBE-585. Examples of the silane coupling agent having an isocyanate group include KBE-9007 and X-12-1159L. Examples of the silane coupling agent having an isocyanurate group include KBM-9659. Examples of the silane coupling agent having a mercapto group include KBM-802 and 803, X-12-1154, and X-12-1156. The silane coupling agent may be a silane coupling agent having a methacryloyl group. The silane coupling agents can be used alone or in combination of two or more kinds thereof.

A content of the silane coupling agent may be 0.01 to 10 parts by mass, 0.1 to 8 parts by mass, or 0.5 to 5 parts by mass, with respect to 100 parts by mass of the total amount of the component (A) and the component (B).

### (Rust Inhibitor)

The photosensitive resin composition according to the present embodiment may further contain a rust inhibitor from the viewpoint of suppressing corrosion of the copper wiring or preventing discoloration. Examples of the rust inhibitor include a triazole derivative such as benzotriazole and a tetrazole derivative. The rust inhibitors may be used alone or in combination of two or more kinds thereof.

A content of the rust inhibitor may be 0.01 to 10 parts by mass, 0.1 to 5 parts by mass, or 0.5 to 3 parts by mass, with respect to 100 parts by mass of the total amount of the component (A) and the component (B).

### (Polymerization Inhibitor)

The photosensitive resin composition according to the present embodiment may further contain a polymerization inhibitor. By using the polymerization inhibitor, the storage stability of the photosensitive resin composition can be secured.

Examples of the polymerization inhibitor include 4-tert-butylcatechol, 4-hydroxy-2,2,6,6-tetramethylpiperidine-1-oxy radical, p-methoxyphenol, diphenyl-p-benzoquinone, benzoquinone, hydroquinone, pyrogallol, phenothiazine, resorcinol, ortho-dinitrobenzene, para-dinitrobenzene, meta-dinitrobenzene, phenanthraquinone, N-phenyl-2-naphthylamine, cupferron, 2,5-toluquinone, tannic acid, para-benzylaminophenol, tris(4-tert-butyl-3-hydroxy-2,6-dimethylbenzyl)isocyanuric acid, and nitrosamines. The polymerization inhibitors may be used alone or in combination of two or more kinds thereof.

A content of the polymerization inhibitor may be 0.01 to 10 parts by mass, 0.05 to 5 parts by mass, or 0.10 to 2 parts by mass, with respect to 100 parts by mass of the total amount of the component (A) and the component (B).

### (Sensitizer)

The photosensitive resin composition may further contain a sensitizer from the viewpoint of achieving both maintenance of a residual film ratio in a wide range of exposure amount and excellent resolution.

Examples of the sensitizer include Michler's ketone, benzoin, 2-methylbenzoin, benzoin methyl ether, benzoin ethyl ether, benzoin isopropyl ether, benzoin butyl ether, 2-t-butylanthraquinone, 1,2-benzo-9,10-anthraquinone, anthraquinone, methylanthraquinone, 4,4′-bis(diethylamino)benzophenone, acetophenone, benzophenone, thioxanthone, 1,5-acenaphthene, 2,2-dimethoxy-2-phenylacetophenone, 1-hydroxycyclohexyl phenyl ketone, 2-methyl-[4-(methylthio)phenyl]-2-morpholino-1-propanone, diacetyl benzyl, benzyldimethyl ketal, benzyldiethyl ketal, diphenyl disulfide, anthracene, phenanthrene quinone, riboflavin tetrabutyrate, acridine orange, erythrosine, phenanthrenequinone, 2-isopropylthioxanthone, 2,6-bis(p-diethylaminobenzylidene)-4-methyl-4-azacyclohexanone, 6-bis(p-dimethylaminobenzylidene)-cyclopentanone, 2,6-bis(p-diethylaminobenzylidene)-4-phenylcyclohexanone, aminostyryl ketone, a 3-ketocoumarin compound, a biscoumarin compound, N-phenylglycine, N-phenyldiethanolamine, and 3,3′,4,4′-tetra(t-butylperoxycarbonyl)benzophenone. The sensitizers may be used alone or in combination of two or more kinds thereof.

When the photosensitive resin composition contains a sensitizer, a content thereof is preferably 0.1 to 2.0 parts by mass, and more preferably 0.2 to 1.5 parts by mass, with respect to 100 parts by mass of the component (A).

### (Solvent)

When the photosensitive resin composition according to the present embodiment contains a solvent for dissolving and dispersing each component, the photosensitive resin composition can be easily applied onto a substrate to form a coating film having a uniform thickness. The solvents may be used alone or in combination of two or more kinds thereof.

Examples of the solvent include ketones such as methyl ethyl ketone, cyclohexanone, and cyclopentanone; aromatic hydrocarbons such as toluene, xylene, mesitylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol dimethyl ether, dipropylene glycol diethyl ether, and triethylene glycol monoethyl ether; esters such as ethyl acetate, butyl acetate, butyl cellosolve acetate, carbitol acetate, and γ-butyrolactone; and nitrogen-containing compounds such as N,N-dimethylformamide, N,N-dimethylacetamide, N-methyl-2-pyrrolidone, N-ethyl-2-pyrrolidone, 3-methoxy-N,N-dimethylpropanamide, and 3-butoxy-N,N-dimethylpropanamide.

A blending amount of the solvent is not particularly limited, and may be an amount in which a solid content in the photosensitive resin composition is 5 to 60 mass %, 10 to 50 mass %, or 15 to 40 mass %.

The preparation means, conditions, and the like of the photosensitive resin composition are not particularly limited. Examples thereof include a method in which the respective main components are sufficiently uniformly stirred and mixed in predetermined blending amounts by a mixer or the like, and then kneaded by using a mixing roll, an extruder, a kneader, a roll, an extruder, or the like. The kneading method is not particularly limited.

A relative dielectric constant of the cured product of the photosensitive resin composition according to the present embodiment at 10 GHz may be 2.80 or less, 2.70 or less, 2.65 or less, or 2.60 or less. A dielectric loss tangent of the cured product of the photosensitive resin composition at 10 GHz may be 0.0050 or less, 0.0045 or less, 0.004 or less, or 0.0030 or less. The relative dielectric constant and the dielectric loss tangent can be measured by the method described in Examples using a cured film of the photosensitive resin composition.

The photosensitive resin composition according to the present embodiment can form a fine pattern. The photosensitive resin composition according to the present embodiment can form an insulating film exhibiting low dielectric characteristics and excellent insulation reliability. A semiconductor element including an interlayer insulating layer formed using a cured product of the photosensitive resin composition described above, and an electronic device including the semiconductor element can be produced. The semiconductor element includes a redistribution layer containing the cured product of the photosensitive resin composition according to the present embodiment, such that high frequency characteristics can be improved. The semiconductor element may be, for example, a memory, a package, or the like having a multilayer wiring structure, a redistribution structure, or the like. Examples of the electronic device include a mobile phone, a smartphone, a tablet terminal, a personal computer, and a hard disk suspension. By including a patterned cured film formed of the photosensitive resin composition of the present embodiment, it is possible to provide a semiconductor element and an electronic device having excellent reliability.

### EXAMPLES

Hereinafter, the present disclosure will be described in more detail with reference to Examples, but the present invention is not limited to these Examples.

### [Synthesis of Maleimide Compound]

In order to synthesize a maleimide compound, the following components (a1) to (a3), an acid catalyst, and a solvent were prepared.

(Component (a1))
TDA-100: 1,3,3a,4,5,9b-hexahydro-5(tetrahydro-2,5-dioxo-3-furanyl)naphtho[1,2-C]furan-1,3-dione (trade name “TDA-100”, manufactured by New Japan Chemical Co., Ltd.)
BPAF: 9,9-bis(3,4-dicarboxyphenyl)fluorene dianhydride (trade name “BPAF”, manufactured by JFE Chemical Corporation)
PMDA: pyromellitic anhydride (manufactured by Daicel Corporation)
BPDA: 3,3′,4,4′-biphenyltetracarboxylic dianhydride (trade name “BPDA”, manufactured by JFE Chemical Corporation)
   (Component (a2))
DDA: dimer diamine (trade name “PRIAMINE 1075”, manufactured by Croda Japan K.K.)
NBDA: norbornanediamine (manufactured by Mitsui Fine Chemicals, Inc.)
mTBHG: 4,4′-diamino-2,2′-dimethylbiphenyl (trade name “m-TB-HG”, manufactured by Wakayama Seika Kogyo Co., Ltd.)
BPF-AN: 9,9-bis[4-(4-aminophenoxy)phenyl]fluorene (trade name “BPF-AN”, manufactured by JFE Chemical Corporation)
   (Component (a3))
Maleic anhydride (manufactured by FUSO CHEMICAL CO., LTD.)

### (Acid Catalyst)

Methanesulfonic acid aqueous solution (trade name “Lutropur MSA”, manufactured by BASF SE)

### (Solvent)

T-SOL100 (aromatic high-boiling solvent, manufactured by ENEOS Corporation)
SOLMIX A-11 (alcoholic solvent, manufactured by Japan Alcohol Trading Co., Ltd.)
Toluene (manufactured by Yamaichi Chemical Industries Co., Ltd.)
Pseudocumene (aromatic high-boiling solvent, manufactured by Toyo Gosei Co., Ltd.)
γ-Butyrolactone (manufactured by FUJIFILM Wako Pure Chemical Corporation)

### Synthesis Example A1

Into a 1 L flask vessel equipped with a condenser, a nitrogen introducing tube, a thermocouple, and a stirrer, 24.35 parts by mass of 1,3,3a,4,5,9b-hexahydro-5(tetrahydro-2,5-dioxo-3-furanyl)naphtho[1,2-C]furan-1,3-dione (TDA-100), 132.69 parts by mass of T-SOL100 (aromatic high-boiling solvent), and 29.33 parts by mass of SOLMIX A-11 (alcoholic solvent) were introduced. After the introduction, the temperature was raised to 80° C., the mixture was kept warm for 0.5 hours, and 40.68 parts by mass of a dimer diamine (DDA) was added dropwise. After the dropwise addition, 5.01 parts by mass of norbornanediamine (NBDA) was added. After the addition, 2.08 parts by mass of a methanesulfonic acid aqueous solution was added, and the temperature was raised to 160° C. After raising the temperature, 40.00 parts by mass of toluene was added, and a dehydration ring-closing reaction was performed at 160° C. for 1 hour to remove water and alcohol in the reaction solution, thereby obtaining an intermediate polyimide. Subsequently, the obtained polyimide was cooled to 130° C., 7.96 parts by mass of maleic anhydride was added, the temperature was raised to 160° C., a dehydration ring-closing reaction was performed at 160° C. for 4 hours, and water in the reaction solution was removed, thereby obtaining a maleimide compound.

The obtained maleimide compound was placed in a separatory funnel, 500 parts by mass of pure water was added thereto, and the separatory funnel was shaken and allowed to stand. After the standing, an aqueous layer and an organic layer were separated, and then only the organic layer was recovered. The recovered organic layer was introduced into a 1 L glass vessel equipped with a condenser, a nitrogen introducing tube, a thermocouple, a stirrer, and a vacuum pump, the temperature was raised to 88 to 93° C., and then, water was removed. Thereafter, the temperature was raised to 100° C., and the solvent was removed for 0.5 hours in a state where the pressure was reduced from the atmospheric pressure by 0.1 MPa, thereby obtaining a maleimide compound (A-1) as a component (A).

A molecular weight of the maleimide compound (A-1) was measured by GPC. 50 μL of a sample obtained by dissolving the maleimide compound in tetrahydrofuran (THF) so as to have a concentration of 3 mass % was injected into columns (GL-R420 (manufactured by Hitachi High-Tech Fielding Corporation)×1, GL-R430 (manufactured by Hitachi High-Tech Fielding Corporation)×1, and GL-R440 (manufactured by Hitachi High-Tech Fielding Corporation)×1) heated to 30° C., and the measurement was performed under the condition of a flow rate of 1.6 mL/min using THF as a developing solvent. As a detector, L-3350 RI detector (manufactured by Hitachi, Ltd.) was used, and the weight average molecular weight (Mw) was converted from the elution time by a molecular weight/elution time curve created using standard polystyrene (manufactured by Tosoh Corporation). The Mw of (A-1) was 10,900.

### Synthesis Example A2

Into a 0.3 L flask vessel equipped with a condenser, a nitrogen introducing tube, a thermocouple, and a stirrer, 29.22 parts by mass of 9,9-bis(3,4-dicarboxyphenyl)fluorene dianhydride (BPAF), 125.71 parts by mass of pseudocumene, 26.95 parts by mass of SOLMIX A-11, and 29.00 parts by mass of γ-butyrolactone were introduced. After the introduction, the temperature was raised to 80° C., the mixture was kept warm for 0.5 hours, 31.95 parts by mass of a dimer diamine (DDA) was added dropwise, and 5.41 parts by mass of 4,4′-diamino-2,2′-dimethylbiphenyl (mTBHG) was then added. After the addition, 1.63 parts by mass of a methanesulfonic acid aqueous solution was added, and the temperature was raised to 160° C. After raising the temperature, 40.00 parts by mass of toluene was added, and a dehydration ring-closing reaction was performed at 160° C. for 1 hour to remove water and alcohol in the reaction solution, thereby obtaining an intermediate polyimide resin. Subsequently, the polyimide resin was cooled to 130° C., 6.25 parts by mass of maleic anhydride was added, the temperature was raised to 160° C., a dehydration ring-closing reaction was performed at 160° C. for 4 hours, and water in the reaction solution was removed, thereby obtaining a maleimide compound.

The obtained maleimide compound was placed in a separatory funnel, 500 parts by mass of pure water was added thereto, and the separatory funnel was shaken and allowed to stand. After the standing, an aqueous layer and an organic layer were separated, and then only the organic layer was recovered. The recovered organic layer was introduced into a 1 L glass vessel equipped with a condenser, a nitrogen introducing tube, a thermocouple, a stirrer, and a vacuum pump, the temperature was raised to 88 to 93° C., and then, water was removed. Thereafter, the temperature was raised to 100° C., and the solvent was partially removed for 0.5 hours in a state where the pressure was reduced from the atmospheric pressure by 0.1 MPa, thereby obtaining a solution of a maleimide compound (A-2) as a component (A).

### Synthesis Examples A3 to A6

Solutions of maleimide compounds (A-3) to (A-6) were obtained in the same manner as that of Synthesis Example A2, except that the blending amounts of the respective components were changed as shown in Table 1.

### Synthesis Example A7

Into a 0.3 L flask vessel equipped with a condenser, a nitrogen introducing tube, a thermocouple, and a stirrer, 39.39 parts by mass of 9,9-bis(3,4-dicarboxyphenyl)fluorene dianhydride (BPAF), 165.77 parts by mass of T-SOL100, and 35.04 parts by mass of SOLMIX A-11 were introduced. After the introduction, the temperature was raised to 80° C., the mixture was kept warm for 0.5 hours, and 43.07 parts by mass of a dimer diamine (DDA) was added dropwise. After the dropwise addition, 5.30 parts by mass of norbornanediamine (NBDA) was sequentially added dropwise, and after the dropwise addition, the mixture was kept warm at 80° C. for 0.5 hours. After keeping the temperature, 2.20 parts by mass of a methanesulfonic acid aqueous solution was added. Thereafter, the temperature was raised to 160° C. while removing the alcohol in the reaction solution. After raising the temperature, 50.00 parts by mass of toluene was added, and a dehydration ring-closing reaction was performed at 160° C. for 2 hours to remove water and alcohol in the reaction solution, thereby obtaining an intermediate polyimide resin. Subsequently, the obtained polyimide resin was cooled to 130° C., 8.42 parts by mass of maleic anhydride was added, the temperature was raised to 160° C., a dehydration ring-closing reaction was performed at 160° C. for 4 hours, and water in the reaction solution was removed, thereby obtaining a maleimide compound.

The obtained maleimide compound was placed in a separatory funnel, 500 parts by mass of pure water was added thereto, and the separatory funnel was shaken and allowed to stand. After the standing, an aqueous layer and an organic layer were separated, and then only the organic layer was recovered. The recovered organic layer was introduced into a 0.3 L glass vessel equipped with a condenser, a nitrogen introducing tube, a thermocouple, a stirrer, and a vacuum pump, the temperature was raised to 88 to 93° C., and then, water was removed. Thereafter, the temperature was raised to 100° C., and the solvent was partially removed for 0.5 hours in a state where the pressure was reduced from the atmospheric pressure by 0.1 MPa, thereby obtaining a solution of a maleimide compound (A-7) as a component (A).

### Synthesis Example A8

A solution of a maleimide compound (A-8) was obtained in the same manner as that of Synthesis Example A7, except that the blending amounts of the respective components were changed as shown in Table 2.

### Synthesis Example A9

A solution of a maleimide compound (A-9) was obtained in the same manner as that of Synthesis Example A7, except that BPAF was changed to 1,3,3a,4,5,9b-hexahydro-5(tetrahydro-2,5-dioxo-3-furanyl)naphtho[1,2-C]furan-1,3-dione (TDA-100), the norbornanediamine was changed to 9,9-bis[4-(4-aminophenoxy)phenyl]fluorene (BPF-AN), and the blending amounts of the respective components were changed as shown in Table 2.

### (Non-Volatile Content)

0.75 g±0.25 g of the solution of the maleimide compound was weighed on a metal petri dish with a precision balance, and then dried at 150° C. for 0.5 hours with a hot air dryer, and the non-volatile content (NV) was calculated using the following equation.

$$NV ( mass \% ) = \{ ( W 3 - W 1 ) / W 2 \} \times 100$$

W1: mass (g) of empty metal petri dish
W2: mass (g) of solution of maleimide compound before drying
W3: mass (g) of metal petri dish+maleimide compound after drying

TABLE 1

| | | A-2 | A-3 | A-4 | A-5 | A-6 |
|---|---|---|---|---|---|---|
| Component (a1) | BPAF | 29.22 | 18.88 | 19.77 | 18.91 | 20.46 |
| | PMDA | — | — | 9.41 | 9.00 | 9.73 |
| | BPDA | — | 12.12 | — | — | — |
| Component (a2) | DDA | 31.95 | 40.21 | 42.09 | 29.53 | 28.19 |
| | mTBHG | 5.41 | 6.82 | 7.13 | 11.68 | 11.15 |
| Component (a3) | Maleic anhydride | 6.25 | 7.87 | 8.24 | 8.09 | 4.63 |
| Acid catalyst | Methanesulfonic acid | 1.63 | 2.06 | 2.15 | 2.11 | 1.21 |
| | aqueous solution | | | | | |
| Solvent | Pseudocumene | 125.71 | 125 | 130.84 | 131.01 | 131.65 |
| | SOLMIX A-11 | 26.95 | 27.87 | 29.18 | 29.11 | 28.99 |
| | Toluene | 40.00 | 40.00 | 40.00 | 40.00 | 40.00 |
| | γ-Butyrolactone | 29.00 | 31.00 | 31.00 | 30.00 | 30.00 |

| | | | | | |
|---|---|---|---|---|---|
| NV (mass %) | 50.4 | 55.4 | 55.2 | 43.5 | 39.6 |
| Mw | 11500 | 11200 | 10800 | 9300 | 17300 |

TABLE 2

| | | A-7 | A-8 | A-9 |
|---|---|---|---|---|
| Component (a1) | BPAF | 39.39 | 39.39 | — |
| | TDA-100 | — | — | 25.78 |
| Component (a2) | Dimer diamine | 43.07 | 30.76 | 30.75 |
| | Norbornanediamine | 5.30 | 8.83 | — |
| | BPF-AN | — | — | 30.51 |
| Component (a3) | Maleic anhydride | 8.42 | 8.42 | 8.42 |
| Acid catalyst | Methanesulfonic | 2.20 | 2.20 | 2.20 |
| | acid aqueous | | | |
| | solution | | | |
| Solvent | T-SOL | 165.77 | 152.06 | 164.87 |
| | SOLMIX A-11 | 35.04 | 32.69 | 35.69 |
| | Toluene | 50.00 | 50.00 | 90.00 |

| | | | |
|---|---|---|---|
| NV (mass %) | 56.0 | 47.2 | 46.0 |
| Mw | 12300 | 11200 | 8800 |

The following compounds were prepared as components (B).

A-DCP: tricyclodecane dimethanol diacrylate (trade name, manufactured by SHIN-NAKAMURA CHEMICAL CO., LTD.)

A-DOG: dioxane glycol diacrylate (trade name, manufactured by SHIN-NAKAMURA CHEMICAL CO., LTD.)

A-9300: tris(2-acryloyloxyethyl)isocyanurate (trade name, manufactured by SHIN-NAKAMURA CHEMICAL CO., LTD.)

DCP: tricyclodecane dimethanol dimethacrylate (trade name, manufactured by SHIN-NAKAMURA CHEMICAL CO., LTD.)

TA-G: 1,3,4,6-tetraallyl glycoluril (trade name, manufactured by SHIKOKU CHEMICALS CORPORATION)

TAIC: triallyl isocyanurate (trade name, manufactured by Mitsubishi Chemical Corporation)

L-DAIC: diallyl isocyanurate (trade name, manufactured by SHIKOKU CHEMICALS CORPORATION)

Polyvinyl benzyl ether compound: the compound prepared in Synthesis Example B1 was used.

### Synthesis Example B1

Into a 500 mL reaction vessel equipped with a stirring device, a thermometer, a reflux tube, and an air pump, 90 parts by mass of a phenol aralkyl resin (trade name “HE100C-30”, manufactured by AIR WATER PERFORMANCE CHEMICAL INC., hydroxyl equivalent: 174 g/eq), 83 parts by mass of chloromethylstyrene (mixture of 17 mass % of o-chloromethylene and 83 mass % of p-chloromethylene, manufactured by Linchuan Chemical Co., Ltd.), 17 parts by mass of tetrabutylphosphonium bromide (manufactured by KANTO CHEMICAL CO., INC.), 6 parts by mass of pure water, 113 parts by mass of toluene, and 23 parts by mass of 2-propanol were introduced, and mixing was performed while stirring at 40° C. and blowing air at a flow rate of 50 mL/min. Next, the temperature was raised to 70° C., and 30 parts by mass of a 48 mass % sodium hydroxide aqueous solution (manufactured by KANTO CHEMICAL CO., INC.) was added dropwise thereto for 20 minutes. After the dropwise addition, the mixture was reacted at 70° C. for 4 hours with stirring, and the reaction solution was cooled to 25° C. and neutralized with a 10 mass % hydrochloric acid aqueous solution. The organic layer of the reaction solution after neutralization was washed three times with pure water, the organic layer was introduced into methanol, and then, a precipitate was recovered to obtain a polyvinyl benzyl ether compound. By measuring an infrared absorption (IR) spectrum of the polyvinyl benzyl ether compound, it was confirmed that the phenol aralkyl resin has a structure in which a phenolic hydroxyl group of the phenol aralkyl resin is substituted with a vinyl benzyl ether group.

The following compounds were prepared as the component (C), the component (D), the coupling agent, the polymerization inhibitor, the rust inhibitor, and the solvent.

Component (C): oxime ester-based photopolymerization initiator (trade name: “Irgacure OXE01” and “Irgacure OXE02”, manufactured by BASF Japan Ltd.)

Component (D): α,α′-bis(t-butylperoxy)diisopropylbenzene (trade name: “PERBUTYL P”, manufactured by NOF CORPORATION)

Coupling agent: 3-methacryloxypropyltrimethoxysilane (trade name “KBM-503”, manufactured by Shin-Etsu Chemical Co., Ltd.)

Polymerization inhibitor: 4-hydroxy-2,2,6,6-tetramethylpiperidine-1-oxy radical (TEMPOL) (manufactured by Tokyo Chemical Industry Co., Ltd.)

Rust inhibitor: 1,2,3-benzotriazole (trade name “BT-120”, manufactured by Johoku Chemical CO., LTD.)

Solvent: mesitylene (manufactured by Toyo Gosei Co., Ltd.)

### [Photosensitive Resin Composition]

The respective components were mixed in the blending amounts (parts by mass, solid content) shown in Table 3, and the mixture was stirred at 25° C. for 30 minutes or longer and then filtered through a filter with a mesh size of 0.5 μm, thereby preparing photosensitive resin compositions of Examples 1 to 10.

### (Dielectric Characteristics)

The photosensitive resin composition was applied onto a copper foil using a knife coater, air-dried for 15 minutes, and dried in a dryer at 90° C. for 15 minutes to form a coating film. The coating film was exposed to light from a high-pressure mercury lamp (exposure amount: 1000 mJ/cm²) and then baked (100° C., 1 minute) on a hot plate after exposure to light to form a resin film having a thickness of 100 μm. Thereafter, the resin film was cured at 200° C. for 2 hours using a clean oven in a nitrogen atmosphere. Subsequently, the copper foil was dissolved and removed with ammonium persulfate to obtain a cured film.

The cured film was cut into a length of 80 mm and a width of 80 mm to prepare an evaluation sample. A relative dielectric constant (Dk) and a dielectric loss tangent (Df) of the evaluation sample at 10 GHz were measured at room temperature using an SPDR dielectric resonator (manufactured by QWED Company) and an analyzer (trade name “PNA Network Analyzer N5227A”, manufactured by Agilent Technologies, Inc.).

### (5% Weight Loss Temperature)

6.0 to 10.0 mg of the cured film was weighed in an open type sample container (trade name “GCA-0055”, manufactured by Hitachi High-Tech Science Corporation), and a 5% weight loss temperature (T_{d5}) was measured under the conditions of a nitrogen flow rate of 300 mL/min, a starting temperature of 40° C., and a heating rate of 10° C./min. As a measuring apparatus, NEXTA STA200RV (manufactured by Hitachi High-Tech Science Corporation) was used.

### (Photosensitive Characteristics)

The photosensitive resin composition was spin-coated onto a silicon wafer, and dried by heating at 90° C. for 5 minutes using a hot plate to form a resin film having a thickness of 8 μm. Next, the resin film was subjected to pattern exposure under the condition of an exposure amount of 300 mJ/cm² using an i-line stepper exposure machine (trade name “Sc6k”, manufactured by CERMA PRECISION, INC.), and then heated at 100° C. for 1 minute using a hot plate. Thereafter, the resin film was immersed in a developer (mixed solution of cyclopentanone and propylene glycol monomethyl ether acetate (PGMEA)) at 25° C. for 20 seconds, and washed with PGMEA. The presence or absence of peeling of the resin film after development from the silicon wafer, cracking of the resin film, or roughness of the patterned end portion, and the presence or absence of a residue of the patterned bottom portion obtained by developing the resin film were confirmed with a metal microscope. A case where the minimum via diameter in which these defects were not confirmed was 20 μm or less was evaluated as “A”, and a case where the minimum via diameter was more than 20 μm was evaluated as “B”

TABLE 3

| Example | | 1 | 2 | 3 | 5 | 6 | 7 | 8 | 9 | 10 |
|---|---|---|---|---|---|---|---|---|---|---|
| (A) | A-1 | 85.0 | 85.0 | 85.0 | 85.0 | 85.0 | 85.0 | 85.0 | 85.0 | 85.0 |
| (B) | A-DCP | 15.0 | — | — | — | — | — | — | — | — |
| | A-DOG | — | 15.0 | — | — | — | — | — | — | — |
| | A-9300 | — | — | 15.0 | — | — | — | — | — | 7.5 |
| | DCP | — | — | — | 15.0 | — | — | — | — | — |
| | TA-G | — | — | — | — | 15.0 | — | — | — | 7.5 |
| | TAIC | — | — | — | — | — | 15.0 | — | — | — |
| | L-DAIC | — | — | — | — | — | — | 15.0 | — | — |
| | Polyvinyl | — | — | — | — | — | — | — | 15.0 | — |
| | benzyl ether | | | | | | | | | |
| | compound | | | | | | | | | |
| (C) | OXE01 | 3.0 | 3.0 | 3.0 | 3.0 | 3.0 | 3.0 | 3.0 | 3.0 | 3.0 |
| (D) | PERBUTYL P | 1.0 | 1.0 | 1.0 | 1.0 | 1.0 | 1.0 | 1.0 | 1.0 | 1.0 |

| | | | | | | | | | |
|---|---|---|---|---|---|---|---|---|---|
| Coupling agent | 1.7 | 1.7 | 1.7 | 1.7 | 1.7 | 1.7 | 1.7 | 1.7 | 1.7 |
| Polymerization | 0.25 | 0.25 | 0.25 | 0.25 | 0.25 | 0.25 | 0.25 | 0.25 | 0.25 |
| inhibitor | | | | | | | | | |
| Rust inhibitor | 1.7 | 1.7 | 1.7 | 1.7 | 1.7 | 1.7 | 1.7 | 1.7 | 1.7 |
| Solvent | 210 | 210 | 210 | 210 | 210 | 210 | 210 | 210 | 210 |
| Dk | 2.47 | 2.50 | 2.48 | 2.48 | 2.51 | 2.54 | 2.52 | 2.53 | 2.50 |
| Df | 0.0026 | 0.0023 | 0.0025 | 0.0019 | 0.0017 | 0.0015 | 0.0015 | 0.0016 | 0.0027 |
| Td5 (° C.) | 403 | 416 | 378 | 389 | 422 | 420 | 422 | 426 | 418 |
| Via diameter | A | A | A | A | A | A | A | A | A |
| evaluation | | | | | | | | | |

The respective components were mixed in the blending amounts (parts by mass, solid content) shown in Table 4, and the mixture was stirred at 25° C. for 30 minutes or longer and then filtered through a filter with a mesh size of 0.5 μm, thereby preparing photosensitive resin compositions of Examples 11 to 15.

### (Photosensitive Characteristics)

The photosensitive resin composition was spin-coated onto a silicon wafer, and dried by heating at 90° C. for 5 minutes to form a resin film having a thickness of 7 μm. Next, the resin film was subjected to pattern exposure under the condition of an exposure amount of 1000 mJ/cm² using a mask aligner-exposure machine (MA-20), and then heated at 100° C. for 1 minute. The silicon wafer on which the resin film after exposure was formed was developed at 25° C. for 15 seconds using a developer (mixed solution of cyclopentanone and PGMEA), and then washed with PGMEA. For the resin film after development, the presence or absence of cracks was confirmed with a metal microscope.

A case where these defects were not confirmed was evaluated as “A”, and a case where defects were confirmed was evaluated as “B”.

TABLE 4

| Example | | 11 | 12 | 13 | 14 | 15 |
|---|---|---|---|---|---|---|
| (A) | A-2 | 85.0 | — | — | — | — |
| | A-3 | — | 85.0 | — | — | — |
| | A-4 | — | — | 85.0 | — | — |
| | A-5 | — | — | — | 85.0 | — |
| | A-6 | — | — | — | — | 85.0 |
| (B) | A-9300 | 5.0 | 5.0 | 5.0 | 5.0 | 5.0 |
| | TAIC | 10.0 | 10.0 | 10.0 | 10.0 | 10.0 |
| (C) | OXE01 | 3.0 | 3.0 | 3.0 | 3.0 | 3.0 |
| | OXE02 | 2.0 | 2.0 | 2.0 | 2.0 | 2.0 |

| | | | | | |
|---|---|---|---|---|---|
| Coupling agent | 1.7 | 1.7 | 1.7 | 1.7 | 1.7 |
| Polymerization inhibitor | 0.25 | 0.25 | 0.25 | 0.25 | 0.25 |
| Rust inhibitor | 1.7 | 1.7 | 1.7 | 1.7 | 1.7 |
| Solvent | 210 | 210 | 210 | 210 | 210 |
| Photosensitive | A | A | A | A | A |
| characteristics | | | | | |

The respective components were mixed in the blending amounts (parts by mass, solid content) shown in Table 5, and the mixture was stirred at 25° C. for 30 minutes or longer and then filtered through a filter with a mesh size of 0.5 μm, thereby preparing photosensitive resin compositions of Examples 16 to 18. The dielectric characteristics, the 5% weight loss temperature, and the photosensitive characteristics were evaluated in the same manner as in Examples 1 to 10.

TABLE 5

| Example | | 16 | 17 | 18 |
|---|---|---|---|---|
| (A) | A-7 | 85.0 | — | — |
| | A-8 | — | 85.0 | — |
| | A-9 | — | — | 85.0 |
| (B) | A-9300 | 15 | 15 | 15 |
| (C) | OXE01 | 3.0 | 3.0 | 3.0 |
| (D) | PERBUTYL P | 1.0 | 1.0 | 1.0 |

| | | | |
|---|---|---|---|
| Coupling agent | 1.7 | 1.7 | 1.7 |
| Polymerization inhibitor | 0.25 | 0.25 | 0.25 |
| Rust inhibitor | 1.7 | 1.7 | 1.7 |
| Solvent | 210 | 210 | 210 |
| Dk | 2.66 | 2.72 | 2.75 |
| Df | 0.0038 | 0.0043 | 0.0047 |
| Td5 (° C.) | 410 | 410 | 410 |
| Via diameter evaluation | A | A | A |

1. A photosensitive resin composition comprising: a base resin containing a maleimide compound; a crosslinking agent; and a photopolymerization initiator,
wherein the maleimide compound is a reaction product of a tetracarboxylic dianhydride, a diamine, and maleic anhydride, and the diamine includes a dimer diamine and a second diamine other than the dimer diamine.

2. The photosensitive resin composition according to claim 1, wherein the tetracarboxylic dianhydride includes at least one selected from the group consisting of 4,4′-(4,4′-isopropylidenediphenoxy)diphthalic anhydride, 4,4′-oxydiphthalic anhydride, and 1,2,3,4-butanetetracarboxylic dianhydride.

3. The photosensitive resin composition according to claim 1, wherein the tetracarboxylic dianhydride includes 1,3,3a,4,5,9b-hexahydro-5(tetrahydro-2,5-dioxo-3-furanyl)naphtho[1,2-C]furan-1,3-dione.

4. The photosensitive resin composition according to claim 1, wherein the second diamine includes at least one selected from the group consisting of meta-xylylenediamine, 4,4′-diaminodiphenylmethane, 1,3-diaminopropane, and 2,2-bis[4-(4-aminophenoxy)phenyl]propane.

5. The photosensitive resin composition according to claim 1, wherein the second diamine includes norbornanediamine.

6. The photosensitive resin composition according to claim 1, wherein the crosslinking agent includes a polymerizable crosslinking agent having a (meth)acryloyl group.

7. The photosensitive resin composition according to claim 6, wherein the polymerizable crosslinking agent having a (meth)acryloyl group includes at least one selected from the group consisting of tricyclodecanedimethanol di(meth)acrylate, tris(2-(meth)acryloyloxyethyl)isocyanurate, and dioxane glycol di(meth)acrylate.

8. The photosensitive resin composition according to claim 1, wherein the crosslinking agent includes a polymerizable crosslinking agent having an allyl group or a vinyl group.

9. The photosensitive resin composition according to claim 8, wherein the polymerizable crosslinking agent having an allyl group or a vinyl group includes at least one selected from the group consisting of 1,3,4,6-tetraallyl glycoluril, triallyl isocyanurate, diallyl isocyanurate, and a polyvinyl benzyl ether compound.

10. The photosensitive resin composition according to claim 1, further comprising a thermal polymerization initiator.

11. A cured product of the photosensitive resin composition according to claim 1.

12. A semiconductor element comprising a redistribution layer containing a cured product of the photosensitive resin composition according to claim 1.
